(19) United States
(12) Patent Application Publication
(10) Pub. No.: US 2009/0205702 A1
(43) Pub. Date: Aug. 20, 2009

(54) Solar panel and associated method

(75) Inventors: Paulus Cornelis De Jong, Aalsmeer (NL); Axel Georg Schönecker, Alkmaar (NL); Jakob Hoornstra, Sint Maartensbrug (NL)

Correspondence Address: FLIESLER MEYER LLP, 650 CALIFORNIA STREET, 14TH FLOOR, SAN FRANCISCO, CA, 94108, US

(73) Assignee: STICHTING ENERGIEONDERZOEK CENTRUM NEDERLAND, Petten (NL)

(21) Appl. No.: 12/304,921

(22) PCT Filed: Jun. 15, 2007
(86) PCT No.: PCT/NL2007/050287

§ 371 Date: Jan. 28, 2009

(30) Foreign Application Priority Data
Jun. 15, 2006 (NL) 2000104

(51) Int. Cl. H01L 31/048; H01L 31/04; H01L 31/18

(52) U.S. Cl. 136/251; 136/252; 438/65

(57) ABSTRACT

Module for a solar panel, comprising a glass plate and a monolithic solar cell, wherein the monolithic solar cell is joined to the glass plate. A glass frit layer is located between the solar cell and the glass plate and forms the join between a surface of the glass plate and a photoactive surface of the solar cell.

This application is a national stage application that claims priority under 35 U.S.C. 371 to Patent Cooperation Treaty Application No. PCT/NL2007/050287, entitled “Solar panel and associated method,” inventors Paulus Cornelis De Jong et al., filed Jun. 15, 2007, and which has been published as Publication No. WO2007/145524, which application is herein incorporated by reference.

### FIELD OF THE INVENTION

The present invention relates to a solar panel module according to the preamble of claim 1. The invention also relates to a method for producing a solar panel module. Furthermore, the invention relates to a solar panel provided with a solar panel module as stated above.

### BACKGROUND OF THE INVENTION

Solar panels comprising one or more monolithic solar cells are known from the prior art. Monolithic solar cells are in plate form and characteristically comprise a semiconductor substrate, which may be either single-crystal or polycrystalline. The solar cell comprises a photoactive surface which under incident light can carry out a photoelectric conversion, with the result that electric power can be generated.

In addition to the monolithic solar cell(s), the solar panel of the prior art comprises a glass plate, a first plastic joining layer, a second plastic joining layer and a rear-side coversheet or glass plate.

The photoactive surface of the solar cell faces towards the glass plate, also known as the superstrate, and is joined to a surface of the glass plate by means of the first plastic joining layer. The other surface of the solar cell, remote from the glass plate, is joined to the rear-side coversheet or glass plate by means of the second plastic joining layer.

The first and second plastic joining layers are responsible for the bonding between glass plate and solar cell and between solar cell and rear side, respectively. The first and second plastic joining layers are also adapted for absorbing thermomechanical stresses between the various layers mentioned above resulting from thermal expansion differences.

Some of the drawbacks of the structure of the solar panel according to the prior art are the material-intensive contribution to the cost price, the complexity of the manufacturing process and the plastics, which age when the solar panel is in use and thereby limit the service life. As a result, for example the transparency of the joining layer may decrease, which is deleterious to the solar cell efficiency. This ageing can also lead to a reduction in the bonding between the various layers of the solar panel, resulting in a disadvantageous drop in the sealing of the solar panel.

U.S. Pat. No. 5,972,732 describes a solar cell module, including a glass plate and a monolithic solar cell. Bonding is done by applying heat and pressure.

The document Roy Knechtel: “Glass frit bonding: an universal technology for wafer level encapsulation and packaging” MICROSYSTEM TECHNOLOGIES; MICRO AND NANOSYSTEMS, SPRINGER-VERSLAG, BE, vol. 12, no. 1-2, 1 Dec. 2005, pages 63-68 describes using a glass-frit layer to join the photoactive surface of the solar cell and the glass plate.

### SUMMARY OF THE INVENTION

It is an object of the present invention to provide a solar panel which overcomes the abovementioned drawbacks of using the plastic joining layers.

According to the present invention, this object is achieved by the characterizing features of claim 1.

This has the advantageous result of providing a durable join between glass plate and solar cell without any ageing during the period of use. Moreover, the invention hereby provides a monolithic solar panel module as a semi-finished product. This semi-finished product is robust and can be used to good effect in the construction of solar panels with any desired number of solar cells therein.

The use of glass frit in solar panels is known in applications for thin-film technologies. In applications of this type, the glass frit is used as a sealing layer along an edge portion between the glass superstrate and the glass substrate (on which the thin-film solar cell is arranged). The function of this seal is to hermetically seal the active solar cell from the outside world, with the result that oxygen and moisture are unable to age and/or degrade the solar cell.

In the present invention, glass frit is used as bonding layer between the solar cell and the glass superstrate.

The invention will be explained in more detail below on the basis of a number of drawings, illustrating exemplary embodiments of the invention. The drawings are only intended to illustrate the objectives of the invention and should not be taken as any restriction on the inventive concept as defined by the accompanying claims.

### BRIEF DESCRIPTION OF THE DRAWINGS

FIG. 1 shows a cross section through a solar panel according to the prior art, which is provided with a monolithic solar cell;

FIG. 2 shows a cross section through a solar panel according to the present invention;

FIG. 3 shows a cross section through a module of a solar panel according to the present invention, and

FIG. 4 shows a temperature profile for use during the method according to the present invention.

### DETAILED DESCRIPTION OF THE DRAWINGS

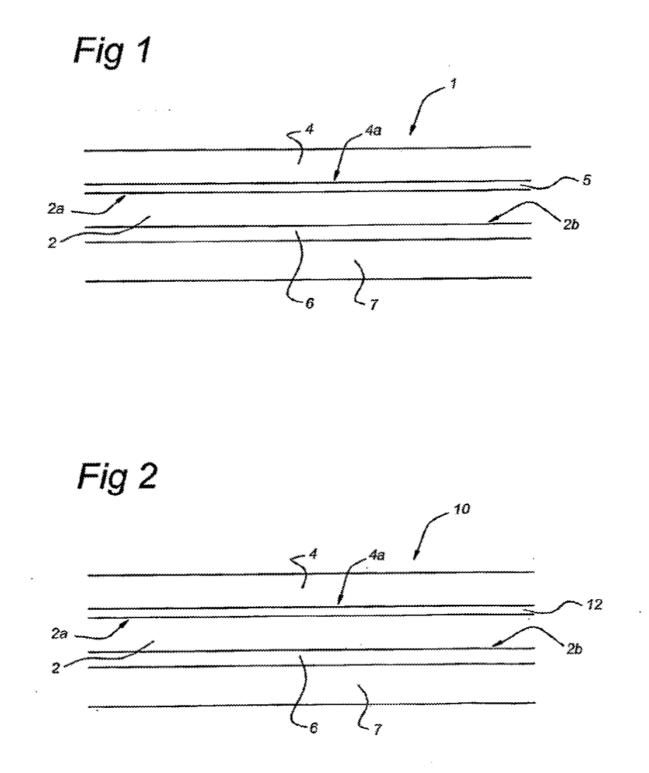

FIG. 1 shows a cross section through a solar panel 1 according to the prior art. In its most customary form, the solar panel 1 is provided with a monolithic solar cell 2, which comprises a plate-like semiconductor substrate, which may be either single-crystal or polycrystalline. The solar cell 2 comprises a photoactive surface 2a which, under incident light, can carry out a photoelectric conversion, with the result that electric power can be generated.

The solar panel 1 also comprises a glass plate 4, a first plastic joining layer 5, a second plastic joining layer 6 and a rear-side sheet or glass plate 7.

The photoactive surface 2a of the solar cell faces towards the glass plate 4 and is joined to a surface 4a of the glass plate 4 by means of the first plastic joining layer 5. The other surface 2b of the solar cell 2, remote from the glass plate, is joined to the rear-side sheet or glass plate 7 by means of the second plastic joining layer 6.

The first and second plastic joining layers 5, 6 consist of a rubber-adhesive material, for example ethylene vinyl acetate (EVA). The rear-side sheet or glass plate 7 comprises, for example, a polyvinyl fluoride (PVF) such as Tedlar or a laminate. The wiring for making electrical connections to the solar cell 2 is not shown.

The solar panel 1 shown in FIG. 1 is typically formed in a batch process.

Building up the solar panel 1 of the prior art comprises placing the glass plate 4, the first plastic joining layer 5, the electrically interconnected solar cells 2, the second plastic joining layer 6 and the rear-side sheet or glass plate 7 on top of one another.

The assembly formed in this way is then treated in a vacuum laminator. The assembly is placed under a vacuum in order to remove air that is present between the stacked components. The assembly is then heated to a temperature (for example to approximately 150° C. if EVA is being used) at which the material of the plastic joining layers 5, 6 is vulcanized and thereby joins glass plate 4 and solar cell 2, on the one hand, and solar cell 2 and rear-side sheet or glass plate 7, on the other hand. After vulcanization, the assembly is removed from the vacuum laminator, after which the laminate formed in this way is cooled to room temperature.

This method of building up the solar panel has the drawback of being relatively labour-intensive, material-intensive and also of entailing a relatively long production time.

FIG. 2 shows a cross section through a solar panel according to the present invention.

Identical reference numerals to those used in the previous figure denote identical parts.

The solar panel 10 in the first embodiment comprises a glass plate or superstrate 4, a monolithic solar cell 2, a plastic joining layer 6 and a rear-side sheet or glass plate 7.

According to the present invention, a surface 4a of the glass plate 4 is joined to a photoactive surface 2a of the solar cell 2 which faces towards the glass plate 4, by means of a glass frit layer 12.

The glass frit layer consists of an optically transparent and relatively low-melting glass material which produces a fixed join between the glass plate surface 4a and the photoactive surface 2a of the solar cell 2. In this context, the term relatively low-melting means that the glass material passes into a liquid, low-viscosity state at a relatively low temperature. This transition temperature is below the process temperatures which occur during solar cell manufacture and below the melting temperature of the glass plate.

The invention advantageously provides a transparent joining layer that is not susceptible to ageing (within the same timescale) compared to the plastic joining layer 5 of the prior art. A further advantage is that the method of building up the solar panel is simplified, as will be explained below.

Furthermore, a glass frit join 12 can provide an optical transparency which is virtually equivalent to that of the glass plate, which is of benefit to the transmission of the incident light to the solar cell 2. It is also possible for a refractive index of the glass frit layer 12 to be advantageously matched so as to realize optimum introduction of light into the solar cell.

The glass frit material should be selected in such a way that it has a coefficient of thermal expansion which makes it possible to absorb differences in thermal expansion (resulting from a difference in coefficient of thermal expansion) between glass plate 4 and solar cell 2.

The thickness of the glass frit layer 12 will also play a role in the (thermal) equilibrium of forces.

If appropriate, the glass frit layer can be applied in such a way as to only partially cover the photoactive surface of the solar cell.

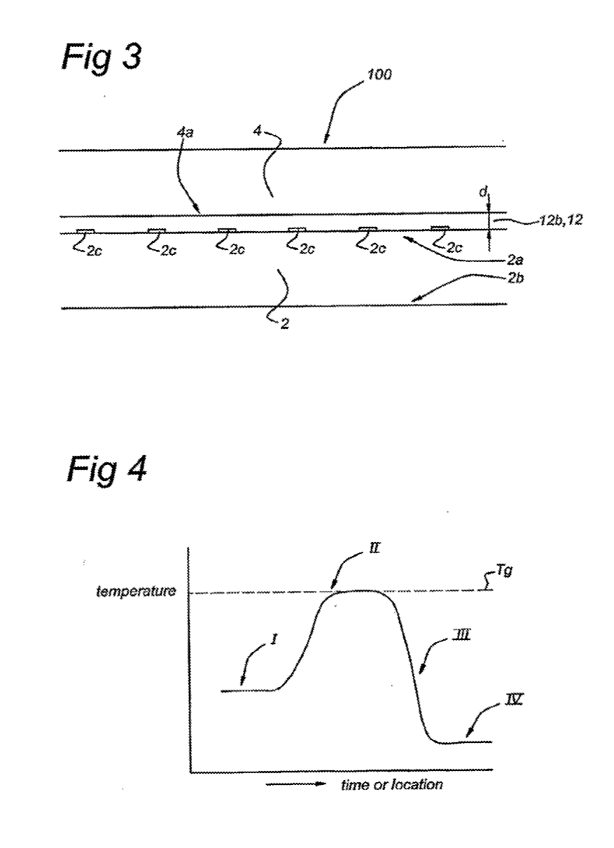

FIG. 3 shows a cross section through a module of a solar panel according to the present invention, following a first manufacturing step.

In a method for producing the solar panel 10 as shown in FIG. 2, in a first step the glass plate 4 is joined to the monolithic solar cell 2.

A glass frit powder 12b is applied in a layer to the surface 4a of the glass plate 4. This can be done, for example, by distributing a suspension of glass frit particles in a liquid over the glass plate surface 4a.

After evaporation of the liquid, a solar cell 2 is placed on this layer of suspension (‘pick-and-place’), during which operation the photoactive surface 2a is brought into contact with the glass frit powder layer 12b.

Evaporation of the liquid can be accelerated by raising the temperature of the glass plate.

Obviously, it is possible for a plurality of solar cells to be arranged next to one another.

Then, the assembly made up of glass plate 4, glass frit powder layer 12 and solar cell(s) 2 is raised to an elevated temperature. At this elevated temperature (i.e. the glass transition temperature), the glass frit powder becomes liquid and flows out to form a substantially continuous layer between glass plate and solar cell. During the flow, a compacting process occurs, during which the porosity of the glass frit layer is eliminated. If appropriate, the assembly made up of glass plate 4, glass frit powder layer 12b and solar cell(s) 2 can be placed under a vacuum in order to allow gas which is enclosed between glass plate and solar cell to be removed.

If appropriate, a compressive force can be exerted on the assembly during the flow process.

After the flow operation, the temperature is reduced, with the result that the glass frit layer 12 changes to a solidified state (glass state).

This results in a semi-finished product module 100 for a solar panel.

This semi-finished product module 100 can, in a further operation, be provided with contacts via a rear-side sheet or glass plate 7. The rear-side sheet or glass plate 7 can be joined to the solar cell 2 via a plastic joining layer 6 as stated above, the difference being that this layer no longer needs to be optically transparent.

Monolithic solar cell types 2 which can suitably be used according to the present invention are solar cell types which are provided with a rear-side contacting (i.e. electrical contacts are located not on the photoactive surface 2a but rather on the other, opposite surface 2b). Solar cell types of this nature include the ‘metal wrap through’ (MWT), ‘emitter wrap through’ (EWT), ‘metal wrap around’ (MWA) and ‘back junction’ (BJ) types.

Although solar cells of the MWT and MWA type do have metallization traces 2c on the photoactive surface 2a for charge transport from or to the photoactive surface, the contact-connections to a further electric circuit are realized on the opposite surface 2b of the solar cell 2.

Suitable glass frit powders preferably have a glass temperature below approx. 500° C. A glass frit suspension consists, for example, of a borosilicate glass powder and ethanol. Other glass frit types based, for example, on lead-containing glass and other liquids can also be used.

The layer thickness of the suspension should be such that after the glass frit flow process the glass frit thickness is at least equal to or greater than the height of the metallization traces on the photoactive surface 2a of the solar cell 2. By way of example, the suspension is applied in a thickness of approx. 100 μm. After evaporation, flow and cooling, the result is a glass frit layer 12 with a thickness of, for example, about 25-50 μm, depending on the particle size distribution of the glass frit powder and working on the basis of a metallization trace height of at most 20 μm.

The abovementioned method can be carried out as a batch process or as an in-line process, in which, in succession, the glass plate is put in place, the glass frit suspension is applied and the solar cell(s) are put in place, after which the heat treatment is carried out to make the glass frit flow and join the glass plate and solar cell to one another.

However, the method according to the present invention can also be carried out using a belt oven, in which case an assembly made up of glass plate, glass frit suspension and solar cell which passes through the belt oven is subjected to a temperature profile which makes the glass frit flow and then solidify so as to join the glass plate and solar cell.

In a preferred embodiment, the assembly of solar cell and glass plate is carried out as an additional step in a glass plate production process.

FIG. 4 diagrammatically depicts a temperature profile for use during the method of the present invention. The temperature curve is shown as a function of time (or in the case of a belt oven as a function of the location within the belt oven).

In a first phase I, the assembly (glass plate, glass frit suspension and solar cell) is held at a slightly elevated temperature in order for the liquid to be evaporated from the suspension. In a subsequent, second phase II, the temperature is raised to a glass temperature Tg of the glass frit, so that the glass frit can flow. During this phase, the temperature Tg will be kept constant for a certain time. The subsequent, third phase III involves cooling, so that the glass frit layer will solidify. The final step is the end phase IV, during which the module 100 that has been formed is removed.

It should be noted that in this example the temperature in the fourth phase IV is lower than in the first phase I. However, it is also possible for the temperature in the fourth phase IV to be higher than or equal to the temperature in the first phase I.

It should be noted that the glass transition temperature Tg (in phase II), on account of the non-crystalline character of the glass frit material, is not sharply defined, unlike the melting temperature of crystalline materials. The flow rate of the glass frit is determined by the temperature of the material. If in relative terms a lower temperature Tg is used in phase II, the flow will therefore be slower than if a higher temperature Tg is used. To compensate for this kinetic effect, the residence time of the assembly at the selected temperature in phase II should be adjusted. A suitable temperature Tg is preferably between approximately 350 and approximately 700° C.

It should also be noted that the rate at which the cooling section III is passed through may influence the level of thermal stresses which are generated in the solar panel 100, on account of the occurrence of time-dependent stress relaxation effects in the glass frit layer 12.

Other alternatives and equivalent embodiments of the present invention are conceivable within the concept of the invention, as will be clear to a person skilled in the field. The concept of the invention is limited only by the accompanying claims.

1-16. (canceled)

17. A module for a solar panel, comprising a glass plate and a monolithic solar cell, wherein the monolithic solar cell is joined to the glass plate, and wherein a glass frit layer, which is located between the solar cell and the glass plate, forms the join between a surface of the glass plate and a photoactive surface of the solar cell, wherein the glass frit layer covers the photoactive surface of the solar cell, and wherein the glass frit layer has an optical transparency which substantially corresponds to the optical transparency of the glass plate, and wherein the glass frit layer has a refractive index which is substantially matched to the refractive index of the glass plate, in order to effect optimum introduction of light into the solar cell.

18. The module according to claim 17, wherein the glass frit layer has a coefficient of thermal expansion with a value which lies between the coefficient of thermal expansion of the solar cell and the coefficient of thermal expansion of the glass plate.

19. The module according to claim 17, wherein the solar cell is one of the following types: ‘metal wrap through’, ‘emitter wrap through’, ‘metal wrap around’ and ‘back junction’.

20. A solar panel provided with a module according to claim 17, also comprising a plastic joining layer and a rear-side support plate, wherein the plastic joining layer forms a join between a surface of the solar cell that is remote from the glass plate and a surface of the rear-side sheet or glass plate.

21. A method for producing a module of a solar panel, comprising a glass plate and a monolithic solar cell, wherein the monolithic solar cell is joined to the glass plate and wherein the method comprises:
forming a joining glass frit layer as the join between a photoactive surface of the solar cell and a surface of the glass plate, wherein the glass frit layer covers the photoactive surface of the solar cell and wherein the glass frit layer has an optical transparency which substantially corresponds to the optical transparency of the glass plate, and wherein the glass frit layer has a refractive index which is substantially matched to the refractive index of the glass plate, in order to effect optimum introduction of light into the solar cell.

22. The method according to claim 21, which also comprises:
applying a glass frit powder layer to a surface of the glass plate;
placing a solar cell on the glass frit powder layer, with a photoactive surface of the solar cell facing towards the glass frit powder layer, and
carrying out a heat treatment, during which
in a first step the glass frit powder layer is heated to a temperature (Tg) at which the glass frit powder layer becomes liquid between the photoactive surface of the solar cell and the surface of the glass plate, and
in a second step the temperature is lowered, so that the liquid glass frit solidifies to form the joining glass frit layer.

23. The method according to claim 22, wherein the glass frit powder layer is applied in the form of a suspension.

24 The method according to claim 23, wherein the heat treatment comprises a step of evaporating a liquid out of the suspension.

25. The method according to claim 23, wherein the thickness of the applied glass frit powder layer is such that a thickness (d) of the joining glass frit layer is greater than a height of metallization traces on the photoactive surface of the solar cell.

26. The method according to claim 21, which comprises:
forming the glass plate.

27. The method according to claim 22, wherein the first step of the heat treatment takes place at between 350° C. and 700° C.

28. The method according to claim 22, wherein at least the first step of the heat treatment is carried out under a vacuum in order to remove enclosed gas between glass plate and solar cell.

29. The method according to claim 22, wherein at least during the first step of the heat treatment a compressive force is applied to the glass plate and the solar cell.
